(19) United States
(12) Patent Application Publication
(10) Pub. No.: US 2008/0145972 A1
(43) Pub. Date: Jun. 19, 2008

(54) PASTE PRINTER AND METHOD OF PRINTING WITH PASTE

(75) Inventors: Tetsuji ISHIKAWA, Kawasaki (JP); Makoto HIRANO, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/860,889

(22) Filed: Sep. 25, 2007

(30) Foreign Application Priority Data
Dec. 15, 2006 (JP) 2006-338793

(51) Int. Cl. H01L 21/00

(52) U.S. Cl. 438/120; 257/E21.001

(57) ABSTRACT

A paste printer allows an electrically-conductive pad formed on a board to be exposed in an opening of a masking member. A removal mechanism is allowed to act on the surface of the electrically-conductive pad within the opening. A rust film is removed from the surface of the electrically-conductive pad. The surface of the electrically-conductive pad gets cleaned. Since the electrically-conductive pad is exposed within the opening of the masking member, the removal mechanism is applied only to the electrically-conductive pad. This results in prevention of damages to the board over an area outside the electrically-conductive pad. In addition, the squeegee serves to supply the electrically-conductive paste to the surface of the electrically-conductive pad through the opening of the masking member. The electrically-conductive pad is covered with the electrically-conductive paste. This results in a reliable prevention of oxidation on the surface of the electrically-conductive pad.

### BACKGROUND OF THE INVENTION

1. Field of the Invention

The present invention relates to a paste printer designed to apply an electrically-conductive paste on an electrically-conductive pad defined on a printed wiring board.

2. Description of the Prior Art

Japanese Patent Application Publication No. 10-79569 discloses a component mounting apparatus, for example. A printed wiring board is supplied to the component mounting apparatus. Electrically-conductive pads are formed on the surface of the printed wiring board. The surfaces of the electrically-conductive pads are subjected to polishing prior to the mounting of a component or components. A polishing unit is utilized. An oxide film is removed from the surface of the individual electrically-conductive pad. The surface of the electrically-conductive pad is cleaned. Solder paste is allowed to spread over the electrically-conductive pad based on a sufficient wetness.

The polishing unit is designed to contact with the entire surface of the printed wiring board. This results in removal of the oxide films from the surfaces of the electrically-conductive pads. However, such contact of the polishing unit causes separation of a resist film from the surface of the printed wiring board, damages to fine electrically-conductive patterns on the surface of the printed wiring board, and the like, because the resist film and the fine electrically-conductive patterns are formed on the surface of the printed wiring board at positions outside the electrically-conductive pad. The printed wiring board cannot thus be a product.

### SUMMARY OF THE INVENTION

It is accordingly an object of the present invention to provide a paste printer and a method of printing paste, capable of cleaning the surface of an electrically-conductive pad without any damage to a board.

According to a first aspect of the present invention, there is provided a paste printer comprising: a masking member having the back surface superimposed on a board, the masking member defining an opening to expose an electrically-conductive pad formed on the board; a removal mechanism designed to act on the surface of the electrically-conductive pad within the opening of the masking member so as to remove a rust film from the surface of the electrically-conductive pad; and a squeegee designed to move along the front surface of the masking member so as to supply electrically-conductive paste to the surface of the electrically-conductive pad through the opening of the masking member.

The paste printer allows the electrically-conductive pad formed on the board to be exposed in the opening of the masking member. The removal mechanism is allowed to act on the surface of the electrically-conductive pad within the opening. The rust film is removed from the surface of the electrically-conductive pad. The surface of the electrically-conductive pad gets cleaned. Since the electrically-conductive pad is exposed within the opening of the masking member, the removal mechanism is applied only to the electrically-conductive pad. This results in prevention of damages to the board over an area outside the electrically-conductive pad. In addition, the squeegee serves to supply the electrically-conductive paste to the surface of the electrically-conductive pad through the opening of the masking member. The cleaned surface of the electrically-conductive pad is covered with the electrically-conductive paste. The surface of the electrically-conductive pad is thus isolated from the oxygen in the atmosphere. This results in a reliable prevention of oxidation on the surface of the electrically-conductive pad.

The removal mechanism may include an ultrasonic vibrator designed to apply ultrasonic vibration to the electrically-conductive paste on the electrically-conductive pad in the paste printer. The ultrasonic vibrator serves to apply the ultrasonic vibration to the surface of the electrically-conductive pad through the electrically-conductive paste. This results in removal of the rust film from the surface of the electrically-conductive pad. The ultrasonic vibrator may be attached to the squeegee.

Alternatively, the removal mechanism may include: a rubber roller designed to rotate around a predetermined rotation axis; and metal wires supported on the rubber roller, the metal wires protruding from the outer periphery of the rubber roller. The rotation of the rubber roller around the rotation axis allows the metal wires to be urged against the surface of the electrically-conductive pad exposed in the opening of the masking member. The metal wires penetrate through the rust film. In this case, a support body may support the squeegee and the rubber roller. The rubber roller may be supported in front of the squeegee.

Otherwise, the removal mechanism may include a brush made of metal wires. The brush is brought into contact with the surface of the electrically-conductive pad exposed within the opening. This results in removal of the rust film from the surface of the electrically-conductive pad. A support body may support the squeegee and the brush in the paste printer. The brush may be supported in front of the squeegee.

Otherwise, the removal mechanism may include a plasma radiator designed to radiate plasma particles to the surface of the electrically-conductive pad. The plasma particles radiated from the plasma radiator collide against the surface of the electrically-conductive pad exposed within the opening. This results in removal of the rust film from the surface of the electrically-conductive pad. A support member may support the squeegee and the plasma radiator. The plasma radiator may be supported in front of the squeegee.

According to a second aspect of the present invention, there is provided a rust film removing apparatus, comprising: a masking member having a back surface superimposed on a board, the masking member defining an opening to expose an electrically-conductive pad formed on the board; and a removal mechanism designed to act on the surface of the electrically-conductive pad within the opening of the masking member so as to remove a rust film from the surface of the electrically-conductive pad. The rust film removing apparatus allows the surface of the electrically-conductive pad to get cleaned without any damages to the board over an area outside the electrically-conductive pad in the same manner as described above.

According to a third aspect of the present invention, there is provided a method of printing a board with paste, comprising: superimposing a masking member on the board for locating an electrically-conductive pad in an opening defined in the masking member, the electrically-conductive pad formed on the board; removing a rust film from the surface of the electrically-conductive pad within the opening of the masking member; and supplying electrically-conductive paste to the surface of the electrically-conductive pad through the opening.

The method allows the electrically-conductive pad to be exposed within the opening of the masking member. The rust film is removed from the surface of the electrically-conductive pad within the opening. The surface of the electrically-conductive pad gets cleaned. Since the opening of the masking member serves to expose only the electrically-conductive pad, the board is prevented from damages over an area outside the electrically-conductive pad. In addition, the electrically-conductive paste is applied to the surface of the electrically-conductive pad through the opening of the masking member. The cleaned surface of the electrically-conductive pad is covered with the electrically-conductive paste. The surface of the electrically-conductive pad is thus isolated from the oxygen in the atmosphere. This results in a reliable prevention of oxidation on the surface of the electrically-conductive pad.

According to a fourth aspect of the present invention, there is provided a method of printing a board with paste, comprising: superimposing a masking member on the board for locating an electrically-conductive pad in an opening defined in the masking member, the electrically-conductive pad formed on the board; moving a squeegee along the surface of the masking member so as to supply electrically-conductive paste to the surface of the electrically-conductive pad through the opening of the masking member; and applying ultrasonic vibration to the electrically-conductive paste on the electrically-conductive pad so as to remove a rust film from the surface of the electrically-conductive pad.

The method allows the electrically-conductive pad to be exposed within the opening of the masking member. The electrically-conductive paste is supplied into the opening. The ultrasonic vibration is applied to the electrically-conductive paste. The rust film is removed from the surface of the electrically-conductive pad. The surface of the electrically-conductive pad gets cleaned. Since the opening of the masking member serves to expose only the electrically-conductive pad, the board is prevented from damages over an area outside the electrically-conductive pad. In addition, the cleaned surface of the electrically-conductive pad is covered with the electrically-conductive paste. The surface of the electrically-conductive pad is thus isolated from the oxygen in the atmosphere. This results in a reliable prevention of oxidation on the surface of the electrically-conductive pad.

According to a fifth aspect of the present invention, there is provided a method of printing paste, comprising: superimposing a masking member on the board for locating an electrically-conductive pad within an opening defined in the masking member, the electrically-conductive pad formed on the board; urging metal wires against the surface of the electrically-conductive pad within the opening so as to penetrate a rust film on the surface of the electrically-conductive pad, the metal wires protruding from the outer periphery of a rubber roller designed to rotate around a predetermined rotation axis; and moving a squeegee along the surface of the masking member so as to supply electrically-conductive paste to the surface of the electrically-conductive pad through the opening of the masking member.

The method allows an electrically-conductive pad to be exposed within the opening of the metal mask. The metal wires are urged against the surface of the electrically-conductive pad within the opening. The metal wires penetrate through the rust film on the electrically-conductive pad. The surface of the electrically-conductive pad gets cleaned. Since the opening of the masking member serves to expose only the electrically-conductive pad, the board is prevented from damages over an area outside the electrically-conductive pad. In addition, the cleaned surface of the electrically-conductive pad is covered with the electrically-conductive paste. The surface of the electrically-conductive pad is thus isolated from the oxygen in the atmosphere. This results in a reliable prevention of oxidation on the surface of the electrically-conductive pad.

According to a sixth aspect of the present invention, there is provided a method of printing paste, comprising: superimposing a masking member on the board for locating an electrically-conductive pad within an opening defined in the masking member, the electrically-conductive pad formed on the board; bringing a brush made of metal wires into contact with the surface of the electrically-conductive pad within the opening of the masking member so as to remove a rust film from the surface of the electrically-conductive pad; and moving a squeegee along the surface of the masking member to apply electrically-conductive paste to the surface of the electrically-conductive pad through the opening of the masking member.

The method allows the electrically-conductive pad to be exposed within the opening of the masking member. The brush is brought into contact with the surface of the electrically-conductive pad within the opening. This results in removal of the rust film from the surface of the electrically-conductive pad. The surface of the electrically-conductive pad gets cleaned. Since the opening of the masking member serves to expose only the electrically-conductive pad, the board is prevented from damages over an area outside the electrically-conductive pad. In addition, the cleaned surface of the electrically-conductive pad is covered by the electrically-conductive paste. The surface of the electrically-conductive pad is thus insulated from the oxygen in the atmosphere. This results in a reliable prevention of oxidation on the surface of the electrically-conductive pad.

According to a seventh aspect of the present invention, there is provided a method of printing paste, comprising: superimposing a masking member on the board for locating an electrically-conductive pad within an opening defined in the masking member, the electrically-conductive pad formed on the board; radiating plasma particles to the surface of the electrically-conductive pad exposed within the opening of the masking member so as to remove a rust film from the surface of the electrically-conductive pad; and moving a squeegee along the surface of the masking member to apply electrically-conductive paste to the surface of the electrically-conductive pad through the opening of the masking member.

The method allows the electrically-conductive pad to be exposed within the opening of the masking member. The plasma particles collide against the surface of the electrically-conductive pad within the opening. This results in removal of the rust film from the surface of the electrically-conductive pad. The surface of the electrically-conductive pad gets cleaned. Since the opening of the masking member serves to expose only the electrically-conductive pad, the board is prevented from damages over an area outside the electrically-conductive pad. In addition, the cleaned surface of the electrically-conductive pad is covered with the electrically-conductive paste. The surface of the electrically-conductive pad is thus isolated from the oxygen in the atmosphere. This results in a reliable prevention of oxidation on the surface of the electrically-conductive pad.

According to an eighth aspect of the present invention, there is provided a method of removing a rust film, comprising: superimposing a masking member on a board for locating an electrically-conductive pad within an opening defined in the masking member, the electrically-conductive pad formed on the board; and removing a rust film from the surface of the electrically-conductive pad within the opening of the masking member. The method allows the surface of the electrically-conductive pad to get cleaned without any damages to the board over an area outside the electrically-conductive pad in the same manner as described above.

According to a ninth aspect of the present invention, there is provided a method of removing a rust film, comprising: superimposing a masking member on a board for locating an electrically-conductive pad within an opening defined in the masking member, the electrically-conductive pad formed on the board; and urging metal wires against the surface of the electrically-conductive pad within the opening so as to penetrate a rust film on the surface of the electrically-conductive pad, the metal wires protruding from an outer periphery of a rubber roller designed to rotate around a predetermined rotation axis. The method allows the surface of the electrically-conductive pad to get cleaned without any damages to the board over an area outside the electrically-conductive pad in the same manner as described above.

According to a tenth aspect of the present invention, there is provided a method of removing a rust film, comprising: superimposing a masking member on a board for locating an electrically-conductive pad within an opening defined in the masking member, the electrically-conductive pad formed on the board; and bringing a brush made of metal wires into contact with the surface of the electrically-conductive pad within the opening of the masking member so as to remove a rust film from the surface of the electrically-conductive pad. The method allows the surface of the electrically-conductive pad to get cleaned without any damages to the board over an area outside the electrically-conductive pad in the same manner as described above.

According to an eleventh aspect of the present invention, there is provided a method of removing a rust film, comprising: superimposing a masking member on a board for locating an electrically-conductive pad within an opening defined in the masking member, the electrically-conductive pad formed on the board; and radiating plasma particles to the surface of the electrically-conductive pad exposed within the opening of the masking member so as to remove a rust film from the surface of the electrically-conductive pad. The method allows the surface of the electrically-conductive pad to get cleaned without any damages to the board over an area outside the electrically-conductive pad in the same manner as described above.

### BRIEF DESCRIPTION OF THE DRAWINGS

The above and other objects, features and advantages of the present invention will become apparent from the following description of the preferred embodiments in conjunction with the accompanying drawings, wherein:

FIG. 1 is a side view schematically illustrating a paste printer according to a first embodiment of the present invention;

FIG. 2 is a side view schematically illustrating the paste printer and a printed wiring board set on the paste printer;

FIG. 3 is a side view schematically illustrating removal of a rust film during application of solder paste to an electrically-conductive pad;

FIG. 4 is a side view schematically illustrating a paste printer according to a second embodiment of the present invention;

FIG. 5 is a side view schematically illustrating metal wires penetrating through a rust film;

FIG. 6 is a side view schematically illustrating a paste printer according to a third embodiment of the present invention;

FIG. 7 is a side view schematically illustrating removal of a rust film;

FIG. 8 is a side view schematically illustrating a paste printer according to a fourth embodiment of the present invention; and

FIG. 9 is a side view schematically illustrating removal of a rust film.

### DESCRIPTION OF THE PREFERRED EMBODIMENTS

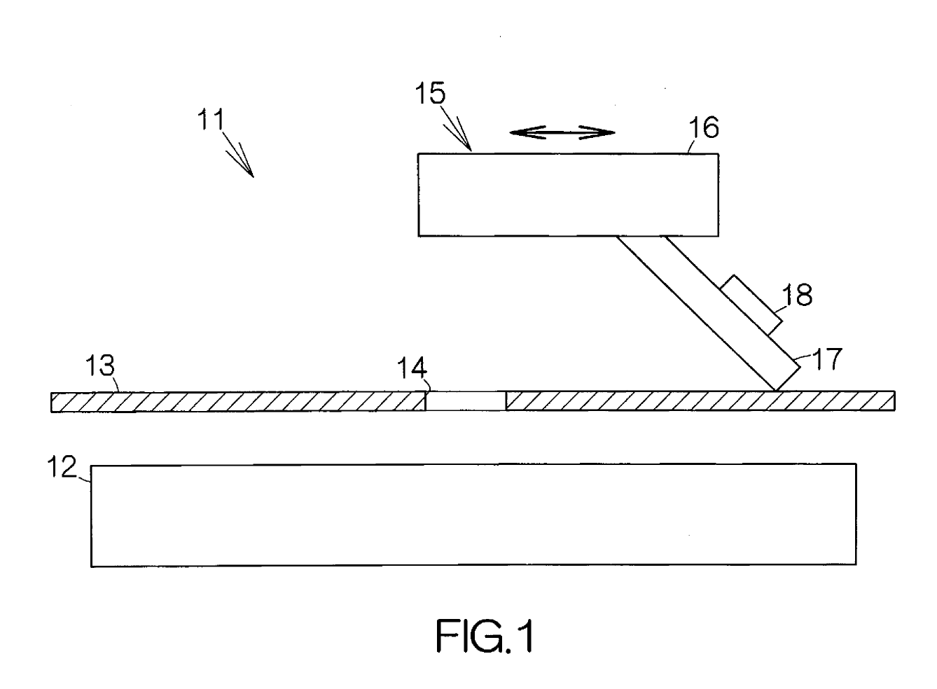

FIG. 1 schematically illustrates a paste printer 11 according to a first embodiment of the present invention. The paste printer 11 includes a stage 12. The stage 12 is designed to support a printed wiring board, not shown. In this case, the stage 12 has the structure of a plate-type. The plate-type allows a plate material to support a printed wiring board on the surface of the plate material. Alternatively, the stage 12 may have the structure of a pin-type. The pin-type allows pins to support a printed wiring board on the tip ends of the pins.

The paste printer 11 includes a masking member, namely a metal mask 13, opposed to the stage 12. The metal mask 13 defines an opening or openings 14. The individual opening 14 serves to expose an electrically-conductive pad on a printed wiring board as described later. The opening 14 is patterned in the shape of the contour of the electrically-conductive pad. The metal mask 13 may be made out of a stainless steel plate, for example. The metal mask 13 has the thickness of 150 μm approximately, for example. Etching process may be employed to form the opening 14 in the stainless steel plate, for example.

A movable unit 15 is related to the metal mask 13. The movable unit 15 is designed to move in parallel with the front surface of the metal mask 13. The movable unit 15 includes a support body 16. The support body 16 is designed to support a metallic squeegee 17. The front surface of the metallic squeegee 17 is opposed to the front surface of the metal mask 13 in an attitude of a predetermined inclination angle relative to the front surface of the metal mask 13. A removal mechanism, namely an ultrasonic vibrator 18, is attached to the back surface of the metallic squeegee 17. The ultrasonic vibrator 18 is designed to apply ultrasonic vibration to the metallic squeegee 17. The frequency of the ultrasonic vibrator 18 is set in a range from 40 kHz to 90 kHz approximately, for example.

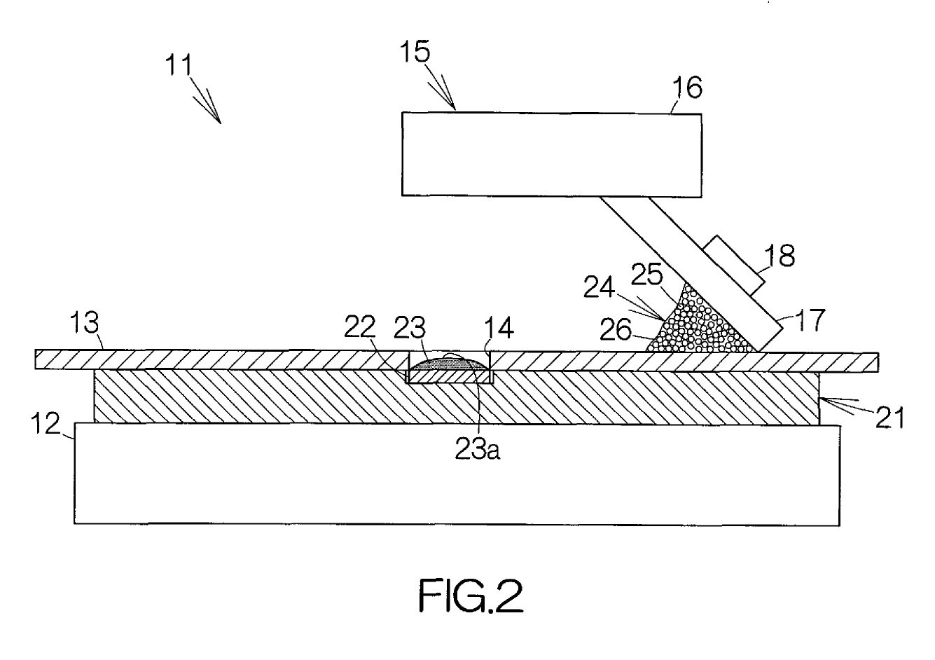

Now, assume that solder paste is to be applied to electrically-conductive pads on a printed wiring board. As shown in FIG. 2, a printed wiring board 21 is set on the stage 12. Electrically-conductive pads 22 are formed on the surface of the printed wiring board 21. The electrically-conductive pads 22 are made of an electrically-conductive material such as copper, for example. In this case, solder leveler 23 is applied to the surface of the electrically-conductive pads 22. The solder leveler 23 is made of an alloy of Sn/3Ag/0.5Cu, for example. In this case, the surface of the solder leveler 23 is covered with a rust film, namely an oxide film 23a.

The metal mask 13 is superimposed on the printed wiring board 21. The back surface of the metal mask 13 is received on the front surface of the printed wiring board 21. The individual electrically-conductive pad 22 is located within the corresponding opening 14 so that the individual electrically-conductive pad 22 gets exposed. The lower end of the metallic squeegee 17 is urged against the surface of the metal mask 13. Solder paste 24 is supplied into a space between the front surface of the metallic squeegee 17 and the front surface of the metal mask 13. Solder paste 24 is comprised of flux 26 and solder particles 25 made of an alloy of Sn/3Ag/0.5Cu, for example. The solder particles 25 have the diameter of 40 μm approximately, for example. The movement of the movable unit 15 is accompanied with the movement of the metallic squeegee 17. The solder paste 24 is moved along the surface of the metal mask 13 in this manner.

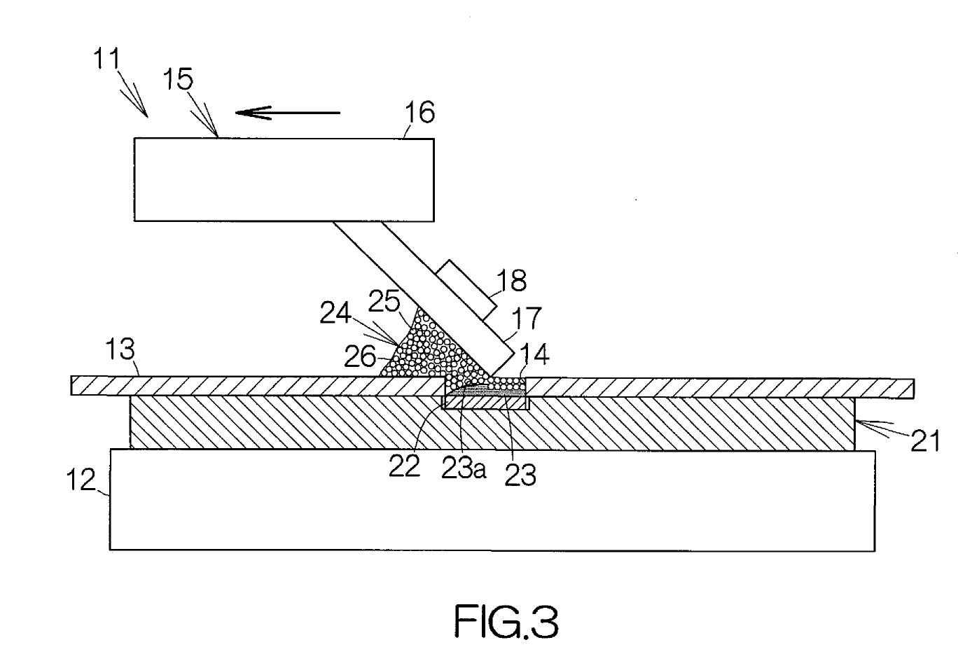

As shown in FIG. 3, when the metallic squeegee 17 passes on the opening 14, the ultrasonic vibrator 18 applies ultrasonic vibration to the metallic squeegee 17. The solder paste 24 is supplied on the electrically-conductive pad 22 through the opening 14. The vibration of the ultrasonic vibrator 18 is transmitted to the solder paste 24 through the metallic squeegee 17. The solder particles 25 vibrate in the flux 26. The vibration of the solder particles 25 acts on the oxide film 23a of the solder leveler 23. The oxide film 23a is thus removed. This results in a reliable contact of the solder particles 25 to the cleaned surface of the solder leveler 23.

When the solder paste 24 has been applied to the surfaces of the electrically-conductive pads 22, the printed wiring board 21 is removed from the paste printer 11. Lead terminals, not shown, of an electronic component are then set on the corresponding electrically-conductive pads 22. The printed wiring board 21 is then set in a reflow oven. The printed wiring board 21 is heated. The solder particles 25 and the solder leveler 23 melt in the reflow oven. The solder paste 24 sufficiently spreads over the surface of the individual electrically-conductive pad 22 based on a sufficient wetness. The printed wiring board 21 is then taken out of the reflow oven. The lead terminals of the electronic component are in this manner fixed on the corresponding electrically-conductive pads 22. The electronic component is mounted on the printed wiring board 21.

The ultrasonic vibration of the ultrasonic vibrator 18 is applied to the surface of the oxide film 23a or surface of individual electrically-conductive pad 22 through the corresponding opening 14 of the metal mask 13 in the paste printer 11. The oxide film 23a is thus removed from the surface of the solder leveler 23. The surfaces of the electrically-conductive pads 22 get cleaned. Since the electrically-conductive pads 22 are exposed within the openings 14 of the metal mask 13, the ultrasonic vibrations are applied only to the electrically-conductive pad 22. This result in prevention of damages to a resist film and fine electrically-conductive patterns, formed outside the electrically-conductive pads 22.

Moreover, the ultrasonic vibrator 18 is attached to the metallic squeegee 17. The ultrasonic vibration is transmitted to the solder paste 24. When the solder paste 24 is supplied on the electrically-conductive pad 22, the oxide film 23a is concurrently removed from the electrically-conductive pad 22. The solder leveler 23 is covered with the solder paste 24. The solder leveler 23 is thus isolated from the oxygen in the atmosphere. This results in a reliable prevention of oxidation on the surface of the solder leveler 23. It should be noted that the paste printer 11 also serves as a rust film removing apparatus according to the present invention.

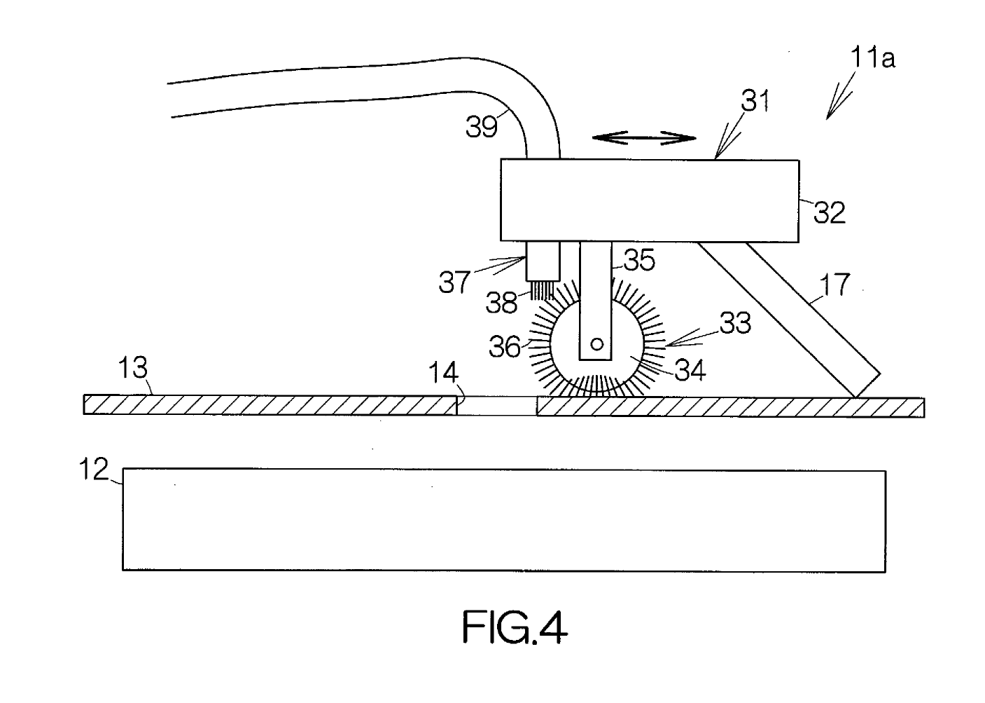

FIG. 4 schematically illustrates a paste printer 11a according to a second embodiment of the present invention. A movable unit 31 is related to the metal mask 13 in the paste printer 11a. The movable unit 31 is opposed to the front surface of the metal mask 13 at a distance. The movable unit 31 is designed to move in parallel with the front surface of the metal mask 13. The movable unit 31 includes a support body 32. The support body 32 is designed to hold the metallic squeegee 17 in a predetermined inclined attitude.

The support member 32 is designed to support a removal mechanism 33 in front of the metallic squeegee 17. Here, the term “front” is defined in accordance with the direction of the advancement of the metallic squeegee 17. The removal mechanism 33 includes a rubber roller 34. The rubber roller 34 is coupled to an arm 35 extending from the support body 32. The rubber roller 34 is supported on the arm 35 for relative rotation around a predetermined rotation axis. The rubber roller 34 may be made a cylindrical rubber, for example.

The rubber roller 34 is designed to support metal wires 36 protruding from the outer periphery of the rubber roller 34. The metal wires 36 are designed to extend outward in the radial directions from the rotation axis. The metal wires 36 are designed to displace in the radial directions of the rubber roller 34 based on the elastic deformation of the rubber roller 34. The metal wires 36 may be tungsten wires, for example. The diameter of the metal wires 36 may be set in a range from 0.05 mm to 0.10 mm approximately, for example.

A suction nozzle 37 is related to the rubber roller 34. The suction nozzle 37 is attached to the support body 32. The suction nozzle 37 includes a brush 38 designed to contact with the metal wires 36 and a hose 39 coupled to the brush 38. The brush 38 is located at a position in the movement path of the metal wires 36. A vacuum pump, not shown, is connected to the hose 39, for example. The operation of the vacuum pump allows suction of air from the tip end of the suction nozzle 37. Like reference numerals are attached to the structure or components equivalent to those of the aforementioned paste printer 11.

Now, assume that the solder paste 24 is to be applied to the electrically-conductive pads 22 on a printed wiring board 21. The printed wiring board 21 is set on the stage 12 in the same manner as described above. Electrically-conductive pads 22 are located in the corresponding openings 14 of the metal mask 13. When the movable unit 31 moves, the solder paste 24 is moved along the front surface of the metal mask 13. The tip ends of the metal wires 36 are stuck into the surface of the metal mask 13. The rubber roller 34 rotates. The elastic deformation of the rubber roller 34 accepts the displacement of the metal wires 36.

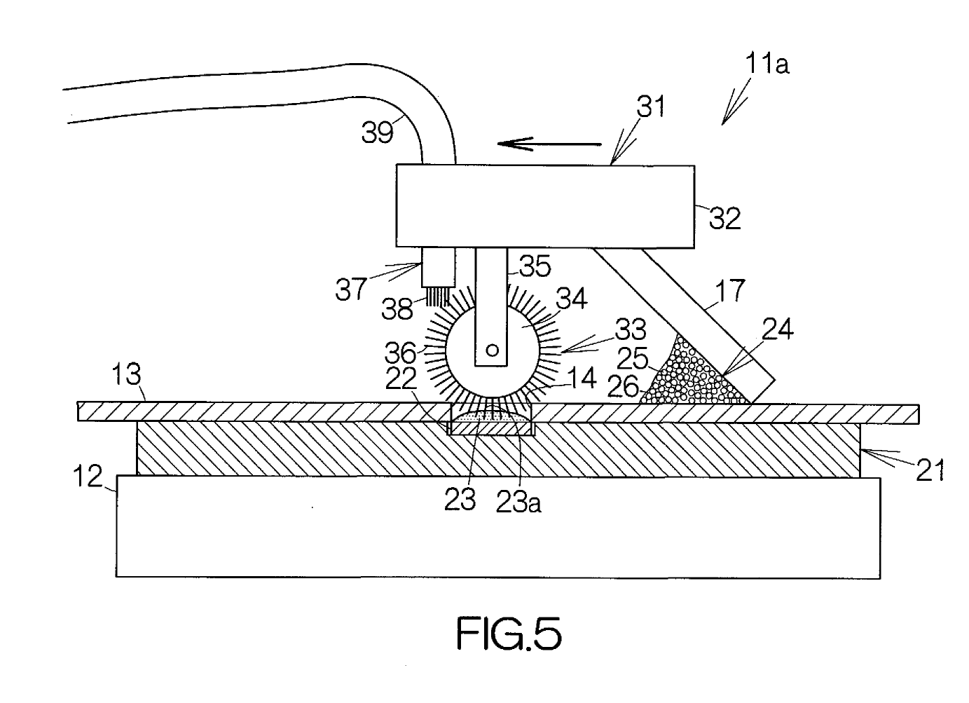

As shown in FIG. 5, when the rubber roller 34 passes on the opening 14, the tip ends of the metal wires 36 stick into the surface of the solder leveler 23. The metal wires 36 thus penetrate through the oxide film 23a. Holes are formed in the oxide film 23a. The rotation of the rubber roller 34 allows the metal wires 36 to contact with the brush 38. The pieces of the oxide film 23a at the tip ends of the metal wires 36 are sucked into the hose 39. This results in prevention of stiction of these pieces to the printed wring board 21. In this specification, the term “removal” or “removing” includes a status where the metal wires 36 penetrate into the oxide film 23a, for example.

When the movable unit 31 further moves, the metallic squeegee 17 serves to apply the solder paste 24 to the electrically-conductive pad 22 through the opening 14. The printed wiring board 21 is then set in a reflow oven in the same manner as described above. The printed wiring board 21 is heated. The solder particles 25 and the solder leveler 23 melt in the reflow oven. The oxide film 23a cracks. Solder of the solder particles 26 is thus mixed with solder of the solder leveler 23. The oxide film 23a is removed in this manner. The printed wiring board 21 is then taken out of the reflow oven. Lead terminals of an electronic component are fixed to the electrically-conductive pad 22. The electronic component is mounted on the printed wiring board 21 in this manner.

The metal wires 36 penetrate through the oxide film 23a in the paste printer 11a. The surfaces of the electrically-conductive pads 22 get cleaned. Since the electrically-conductive pads 22 are exposed within the openings 14 of the metal mask 13, the metal wires 36 are applied only to the electrically-conductive pads 22. This results in prevention of damages to a resist film and fine electrically-conductive patterns, formed outside the electrically-conductive pads 22.

Moreover, the rubber roller 34 is located in front of the metallic squeegee 17. The solder paste 24 is applied to the electrically-conductive pads 22 soon after the metal wires 36 have penetrated through the oxide film 23a. The solder leveler 23 is covered with the solder paste 24. The solder leveler 23 is thus isolated from the oxygen in the atmosphere. This results in a reliable prevention of oxidation on the surface of the solder leveler 23.

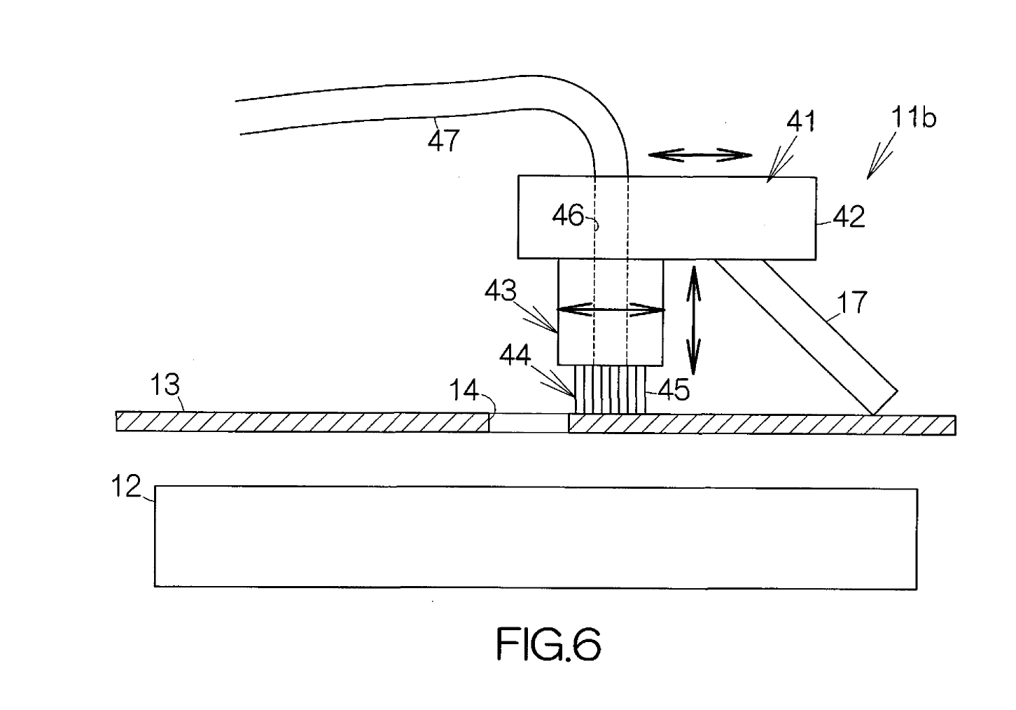

FIG. 6 schematically illustrates a paste printer 11b according to a third embodiment of the present invention. A movable unit 41 is related to the metal mask 13 in the paste printer 11b. The movable unit 41 is opposed to the front surface of the metal mask 13 at a distance. The movable unit 41 is designed to move in parallel with the front surface of the metal mask 13. The movable unit 41 includes a support body 42. The support body 42 is designed to hold the metallic squeegee 17 in a predetermined inclined attitude.

The support member 42 is designed to support a removal mechanism 43 in front of the metallic squeegee 17. Here, the term “front” is defined in accordance with the direction of the advancement of the metallic squeegee 17. The removal mechanism 43 includes a brush 44 coupled to the support body 42. The brush 44 is supported on the support body 42 for relative movement not only in the horizontal direction parallel to the front surface of the metal mask 13 but also in the vertical direction perpendicular to the surface of the metal mask 13. The brush 44 includes metal wires 45 designed to extend straight toward the front surface of the metal mask 13. The metal wires 45 may be made out of stainless steel wires or tungsten wires, for example. The diameter of the metal wires 45 may be set at 0.10 mm approximately, for example.

An air passage 46 is defined in the brush 44. The air passage 46 is designed to reach the upper end of the support body 42. One end of the air passage 46 is connected to the brush 44. The other end of the air passage 46 is connected to a hose 47. A vacuum pump, not shown, is connected to the hose 47, for example. The operation of the vacuum pump allows suction of air from the tip end of the brush 44. Like reference numeral are attached to the structure or components equivalent to those of the aforementioned paste printers 11, 11a.

Now, assume that the solder paste 24 is to be applied to the electrically-conductive pads 22 on a printed wiring board 21. The printed wiring board 21 is set on the stage 12 in the same manner as described above. The electrically-conductive pads 22 are located in the corresponding openings 14 of the metal mask 13. When the movable unit 41 moves, the solder paste 24 is moved along the front surface of the metal mask 13. The brush 44 is kept at rest.

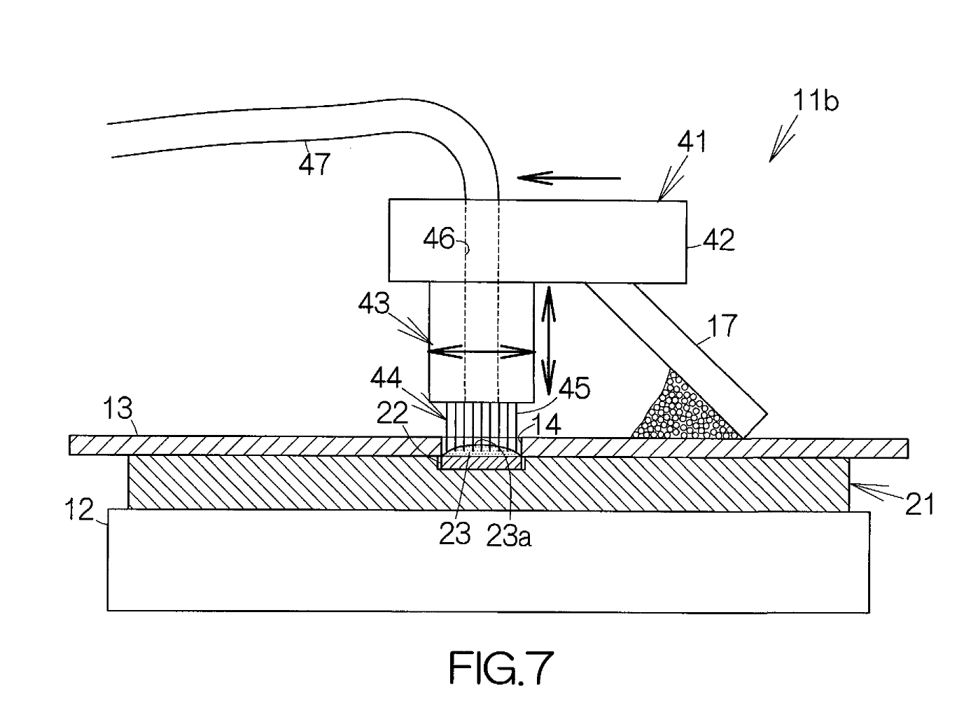

As shown in FIG. 7, when the brush 44 passes on the opening 14, the brush 44 is driven to oscillate in the horizontal and vertical directions. The brush 44 or metal wires 45 thus contact with the surface of the solder leveler 23. The horizontal movement of the brush 44 allows removal of the oxide film 23a from the surface of the solder leveler 23. The pieces of the oxide film 23a stick to the metal wires 45. The pieces of the oxide film 23a at the tip ends of the metal wires 36 are sucked into the air passage 46. This results in prevention of stiction of these pieces to the printed wiring board 21.

When the movable unit 31 further moves, the metallic squeegee 17 serves to apply the solder paste 24 to the electrically-conductive pad 22 through the opening 14. The printed wiring board 21 is then set in a reflow oven in the same manner as described above. The printed wiring board 21 is heated. The solder particles 25 and the solder leveler 23 melt in the reflow oven. The solder paste 24 sufficiently spreads over the individual electrically-conductive pad 22 based on a sufficient wetness. The printed wiring board 21 is then taken out of the reflow oven. The lead terminals of an electronic component are fixed on the corresponding electrically-conductive pad 22. The electronic component is mounted on the printed wiring board 21 in this manner.

The brush 44 serves to remove the oxide films 23a in the paste printer 11b. The surface of the solder leveler 23 gets cleaned. Since the electrically-conductive pads 22 are exposed within the openings 14 of the metal mask 13, the brush 44 is applied only to the electrically-conductive pads 22. This result in prevention of damages to a resist film and fine electrically-conductive patterns, formed outside the electrically-conductive pads 22.

Moreover, the brush 44 is located in front of the metallic squeegee 17. The solder paste 24 is applied to the electrically-conductive pads 22 soon after the metal wires 45 have removed the oxide film 23a. The solder leveler 23 is covered with the solder paste 24. The solder leveler 23 is thus isolated from the oxygen in the atmosphere. This results in a reliable prevention of oxidation on the surface of the solder leveler 23.

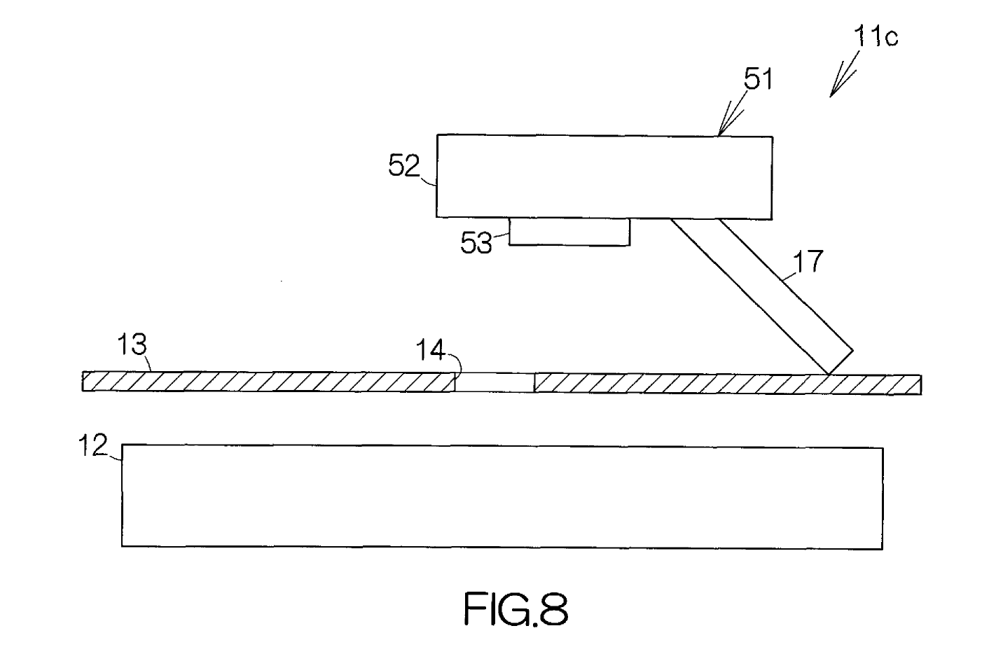

FIG. 8 schematically illustrates a paste printer 11c according to a fourth embodiment of the present invention. A movable unit 51 is related to the metal mask 13 in the paste printer 11c. The movable unit 51 is opposed to the front surface of the metal mask 13 at a distance. The movable unit 51 is designed to move in parallel with the front surface of the metal mask 13. The movable unit 51 includes a support body 52. The support body 52 is designed to hold the metallic squeegee 17 in a predetermined inclined attitude.

The support body 52 is designed to support a removal mechanism, namely a plasma radiator 53, in front of the metallic squeegee 17. Here, the term “front” is defined in accordance with the direction of the advancement of the metallic squeegee 17. The plasma radiator 53 is opposed to the front surface of the metal mask 13 at a distance. The plasma radiator 53 is designed to radiate plasma particles to the surface of the metal mask 13. Like reference numerals are attached to the structure or components equivalent to those of the aforementioned paste printers 11, 11a, 11b.

Now, assume that the solder paste 24 is to be applied to the electrically-conductive pads 22 on a printed wiring board 21. The printed wiring board 21 is set on the stage 12 in the same manner as described above. The electrically-conductive pads 22 are located in the corresponding openings 14 of the metal mask 13. When the movable unit 31 moves, the solder paste 24 is moved along the front surface of the metal mask 13.

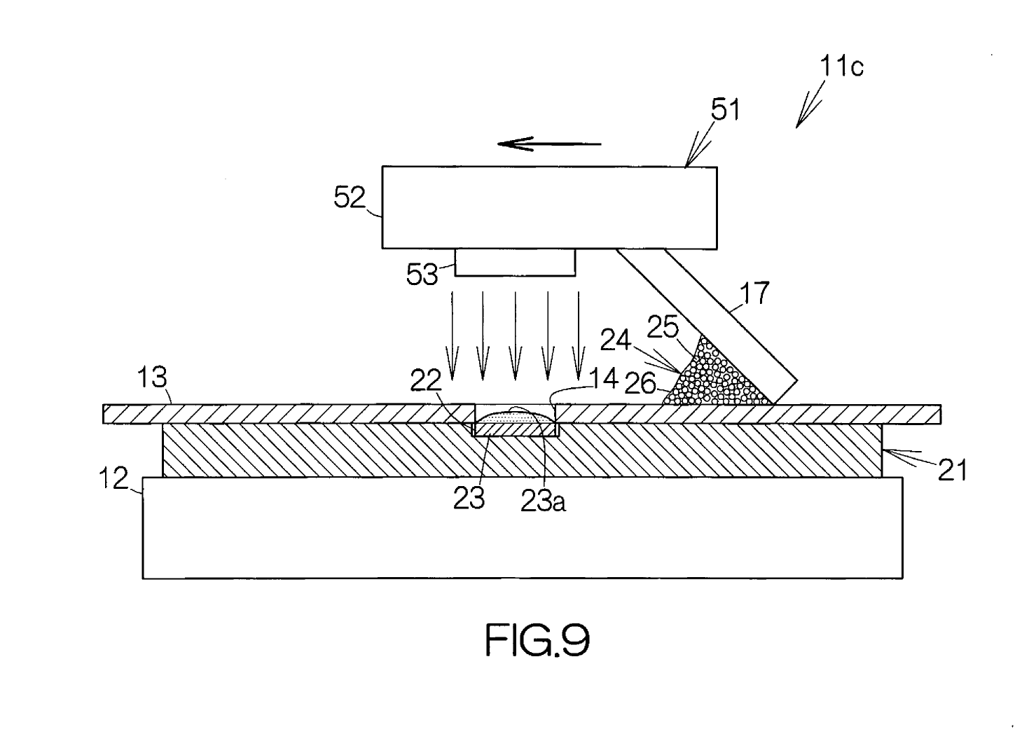

As shown in FIG. 9, when the plasma radiator 53 passes on the opening 14, the plasma radiator 53 radiates plasma particles to the opening 14. The plasma particles falls into the opening 14. The plasma particles collide against the surface of the solder leveler 23, namely the oxide film 23a. This results in removal of the oxide film 23a from the surface of the solder leveler 23.

When the movable unit 51 further moves, the metallic squeegee 17 serves to apply the solder paste 24 to the electrically-conductive pad 22 through the opening 14. The printed wiring board 21 is then set in a reflow oven in the same manner as described above. The printed wiring board 21 is heated. The solder particles 25 and the solder leveler 23 melt in the reflow oven. The solder paste 24 sufficiently spreads over the individual electrically-conductive pad 22 based on a sufficient wetness. The printed wiring board 21 is then taken out of the reflow oven. The lead terminals of an electronic component are fixed on the corresponding electrically-conductive pad 22. The electronic component is mounted on the printed wiring board 21 in this manner.

The collision of the plasma particles allows removal of the oxide film 23a in the paste printer 11c. The surface of the solder leveler 23 gets cleaned. Since the electrically-conductive pads 22 are exposed within the openings 14 of the metal mask 13, the plasma particles are applied only to the electrically-conductive pads 22. This result in prevention of damages to a resist film and fine electrically-conductive patterns, formed outside the electrically-conductive pads 22.

Moreover, the plasma radiator 53 is located in front of the metallic squeegee 17. The solder paste 24 is applied to the electrically-conductive pads 22 soon after the oxide films 23a have been removed. The solder leveler 23 is covered with the solder paste 24. The solder leveler 23 is thus isolated from the oxygen in the atmosphere. This results in a reliable prevention of oxidation of the surface of the solder leveler 23.

What is claimed is:

1. A paste printer comprising:
a masking member having a back surface superimposed on a board, the masking member defining an opening to expose an electrically-conductive pad formed on the board;
a removal mechanism designed to act on a surface of the electrically-conductive pad within the opening of the masking member so as to remove a rust film from the surface of the electrically-conductive pad; and
a squeegee designed to move along a front surface of the masking member so as to supply electrically-conductive paste to the surface of the electrically-conductive pad through the opening of the masking member.

2. The paste printer according to claim 1, wherein the removal mechanism includes an ultrasonic vibrator designed to apply ultrasonic vibration to the electrically-conductive paste on the electrically-conductive pad.

3. The paste printer according to claim 2, wherein the ultrasonic vibrator is attached to the squeegee.

4. The paste printer according to claim 1, wherein the removal mechanism includes:
a rubber roller designed to rotate around a predetermined rotation axis; and
metal wires supported on the rubber roller, the metal wires protruding from an outer periphery of the rubber roller.

5. The paste printer according to claim 4, further comprising a support body designed to support the squeegee and the rubber roller.

6. The paste printer according to claim 4, wherein the rubber roller is supported in front of the squeegee.

7. The paste printer according to claim 1, wherein the removal mechanism includes a brush made of metal wires.

8. The paste printer according to claim 7, further comprising a support body designed to support the squeegee and the brush.

9. The paste printer according to claim 7, wherein the brush is supported in front of the squeegee.

10. The paste printer according to claim 1, wherein the removal mechanism includes a plasma radiator designed to radiate plasma particles to the surface of the electrically-conductive pad.

11. The paste printer according to claim 10, further comprising a support member designed to support the squeegee and the plasma radiator.

12. The paste printer according to claim 10, wherein the plasma radiator is supported in front of the squeegee.

13. A rust film removing apparatus, comprising:
a masking member having a back surface superimposed on a board, the masking member defining an opening to expose an electrically-conductive pad formed on the board; and
a removal mechanism designed to act on a surface of the electrically-conductive pad within the opening of the masking member so as to remove a rust film from the surface of the electrically-conductive pad.

14. The rust film removing apparatus according to claim 13, wherein the removal mechanism includes an ultrasonic vibrator designed to apply ultrasonic vibration to the electrically-conductive paste on the electrically-conductive pad.

15. The rust film removing apparatus according to claim 13, wherein the removal mechanism includes:
a rubber roller designed to rotate around a predetermined rotation axis; and
metal wires supported on the rubber roller, the metal wires protruding from an outer periphery of the rubber roller.

16. The rust film removing apparatus according to claim 13, wherein the removal mechanism includes a brush made of metal wires.

17. The rust film removing apparatus according to claim 13, wherein the removal mechanism includes a plasma radiator designed to radiate plasma particles to the surface of the electrically-conductive pad.

18. A method of printing a board with paste, comprising:
superimposing a masking member on the board for locating an electrically-conductive pad in an opening defined in the masking member, the electrically-conductive pad formed on the board;
removing a rust film from a surface of the electrically-conductive pad within the opening of the masking member; and
supplying electrically-conductive paste to the surface of the electrically-conductive pad through the opening.

19. A method of printing a board with paste, comprising:
superimposing a masking member on the board for locating an electrically-conductive pad in an opening defined in the masking member, the electrically-conductive pad formed on the board;
moving a squeegee along a surface of the masking member so as to supply electrically-conductive paste to a surface of the electrically-conductive pad through the opening of the masking member; and
applying ultrasonic vibration to the electrically-conductive paste on the electrically-conductive pad so as to remove a rust film from the surface of the electrically-conductive pad.

20. A method of printing a board with paste, comprising:
superimposing a masking member on the board for locating an electrically-conductive pad within an opening defined in the masking member, the electrically-conductive pad formed on the board;
urging metal wires against a surface of the electrically-conductive pad within the opening so as to penetrate a rust film on the surface of the electrically-conductive pad, the metal wires protruding from an outer periphery of a rubber roller designed to rotate around a predetermined rotation axis; and
moving a squeegee along a surface of the masking member so as to supply electrically-conductive paste to the surface of the electrically-conductive pad through the opening of the masking member.

21. A method of printing a board with paste, comprising:
superimposing a masking member on the board for locating an electrically-conductive pad within an opening defined in the masking member, the electrically-conductive pad formed on the board;
bringing a brush made of metal wires into contact with a surface of the electrically-conductive pad within the opening of the masking member so as to remove a rust film from the surface of the electrically-conductive pad; and
moving a squeegee along a surface of the masking member to apply electrically-conductive paste to the surface of the electrically-conductive pad through the opening of the masking member.

22. A method of printing a board with paste, comprising:
superimposing a masking member on the board for locating an electrically-conductive pad within an opening defined in the masking member, the electrically-conductive pad formed on the board;
radiating plasma particles to a surface of the electrically-conductive pad exposed within the opening of the masking member so as to remove a rust film from the surface of the electrically-conductive pad; and
moving a squeegee along a surface of the masking member to apply electrically-conductive paste to the surface of the electrically-conductive pad through the opening of the masking member.

23. A method of removing a rust film, comprising:
superimposing a masking member on a board for locating an electrically-conductive pad within an opening defined in the masking member, the electrically-conductive pad formed on the board; and
removing a rust film from a surface of the electrically-conductive pad within the opening of the masking member.

24. A method of removing a rust film, comprising:
superimposing a masking member on a board for locating an electrically-conductive pad within an opening defined in the masking member, the electrically-conductive pad formed on the board; and
urging metal wires against a surface of the electrically-conductive pad within the opening so as to penetrate a rust film on the surface of the electrically-conductive pad, the metal wires protruding from an outer periphery of a rubber roller designed to rotate around a predetermined rotation axis.

25. A method of removing a rust film, comprising:
superimposing a masking member on a board for locating an electrically-conductive pad within an opening defined in the masking member, the electrically-conductive pad formed on the board; and
bringing a brush made of metal wires into contact with a surface of the electrically-conductive pad within the opening of the masking member so as to remove a rust film from the surface of the electrically-conductive pad.

26. A method of removing a rust film, comprising:
superimposing a masking member on a board for locating an electrically-conductive pad within an opening defined in the masking member, the electrically-conductive pad formed on the board; and
radiating plasma particles to a surface of the electrically-conductive pad exposed within the opening of the masking member so as to remove a rust film from the surface of the electrically-conductive pad.
